(19) United States
(12) Patent Application Publication
(10) Pub. No.: US 2024/0355664 A1
(43) Pub. Date: Oct. 24, 2024

(54) SEMICONDUCTOR MANUFACTURING APPARATUS

(71) Applicant: Mitsubishi Electric Corporation, Tokyo (JP)

(72) Inventors: Kinya YAMASHITA, Tokyo (JP); Yasushi TAKAKI, Tokyo (JP); Masaki UENO, Tokyo (JP); Dai KITANO, Tokyo (JP)

(73) Assignee: Mitsubishi Electric Corporation, Tokyo (JP)

(21) Appl. No.: 18/607,622

(22) Filed: Mar. 18, 2024

(30) Foreign Application Priority Data
Apr. 21, 2023 (JP) 2023-070147

(51) Int. Cl. H01L 21/683; H01L 21/687

(52) U.S. Cl. CPC H01L 21/6836; H01L 21/6838; H01L 21/6875; H01L 2221/68327

(57) ABSTRACT

Provided is a semiconductor manufacturing apparatus preventing unnecessary chips from flying off when the semiconductor chips are stripped. A semiconductor manufacturing apparatus stripping the semiconductor chips obtained by dividing an approximately circular wafer into small pieces through dicing, from a dicing sheet on one surface of which the wafer including the semiconductor chips is attached, the apparatus including: a stage including protrusions; a dicing sheet holder; and a gas evacuation device evacuating gases from a space between the stage and the dicing sheet, wherein the protrusions include first protrusions each including a tapered portion that is tapered in a cross-sectional view and an end disposed on a center portion that is an approximately circular region in a center of the stage, and at least one second protrusion without any tapered portion which includes an end disposed on a perimeter portion surrounding the center portion in a plan view.

### BACKGROUND OF THE INVENTION

### Field of the Invention

The present disclosure relates to a semiconductor manufacturing apparatus.

### Description of the Background Art

In steps of manufacturing a semiconductor device, a technology of dicing a wafer attached to a dicing sheet to form semiconductor chips and picking up each of the formed semiconductor chips from the dicing sheet using a pick-up device is sometimes used.

Japanese Patent Application Laid-Open No. 2008-103493 describes a technology of disposing a plurality of protrusions on a stage (jig base) that holds semiconductor chips through a dicing sheet, evacuating gases between the dicing sheet and the stage to strip portions of the dicing sheet other than portions abutted by the protrusions from the semiconductor chips, and picking up the semiconductor chips with the adhesion between the dicing sheet and the semiconductor chips being reduced. Although the cited reference describes an adhesion layer as the dicing sheet, it also mentions application of the dicing sheet instead of the adhesion layer.

In the technology described in the cited reference, however, when gases are evacuated, sometimes, small pieces (hereinafter referred to as unnecessary chips) of a wafer which are produced in a perimeter region of the wafer through dicing are stripped from the dicing sheet, fly off onto semiconductor chips to be products, and damage the semiconductor chips.

### SUMMARY

The present disclosure has an object of providing a semiconductor manufacturing apparatus that can facilitate stripping semiconductor chips from a dicing sheet and prevent unnecessary chips from flying off, in stripping the semiconductor chips.

The semiconductor manufacturing apparatus according to the present disclosure is a semiconductor manufacturing apparatus that strips semiconductor chips from a dicing sheet on one surface of which an approximately circular wafer including the semiconductor chips is attached, the semiconductor chips being obtained by dividing the wafer into small pieces through dicing, the semiconductor manufacturing apparatus including: a stage on which the wafer is disposed through the dicing sheet, the stage including a plurality of protrusions supporting the wafer; a dicing sheet holder holding the dicing sheet; and a gas evacuation device evacuating gases from a space between the stage and the dicing sheet, wherein the plurality of protrusions include a plurality of first protrusions each including a tapered portion that is tapered in a cross-sectional view and an end disposed on a center portion that is an approximately circular region in a center of the stage in a plan view, and at least one second protrusion without any tapered portion which includes an end disposed on a perimeter portion surrounding the center portion in the plan view.

According to the present disclosure, the plurality of protrusions disposed on the stage include the plurality of first protrusions each including a tapered portion that is tapered in a cross-sectional view and an end disposed on a center portion that is an approximately circular region in a center of the stage in a plan view, and at least one second protrusion without any tapered portion which includes an end disposed on a perimeter portion surrounding the center portion in the plan view. This produces an advantage of making facilitating stripping the semiconductor chips that overlap the center portion in the plan view from a dicing sheet compatible with preventing unnecessary chips that overlap the perimeter portion in the plan view from flying off.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view of a semiconductor manufacturing apparatus according to Embodiment 1;

FIG. 2 is a cross-sectional view of the semiconductor manufacturing apparatus according to Embodiment 1;

FIG. 3 is a plan view of a part of the semiconductor manufacturing apparatus according to Embodiment 1;

FIG. 4 is a cross-sectional view of a part of the semiconductor manufacturing apparatus according to Embodiment 1;

FIG. 5 is a cross-sectional view of a part of the semiconductor manufacturing apparatus according to Embodiment 1;

FIG. 6 is a cross-sectional view illustrating semiconductor manufacturing steps according to Embodiment 1;

FIG. 7 is a cross-sectional view illustrating the semiconductor manufacturing steps according to Embodiment 1;

FIG. 8 is a cross-sectional view illustrating the semiconductor manufacturing steps according to Embodiment 1;

FIG. 9 is a cross-sectional view illustrating the semiconductor manufacturing steps according to Embodiment 1;

FIG. 10 is a cross-sectional view illustrating the semiconductor manufacturing steps according to Embodiment 1;

FIG. 11 is a cross-sectional view illustrating the semiconductor manufacturing steps according to Embodiment 1;

FIG. 12 is a plan view of a rough schematic of a wafer;

FIG. 13 is a plan view of a part of a semiconductor manufacturing apparatus according to Embodiment 2; and

FIG. 14 is a cross-sectional view of a part of the semiconductor manufacturing apparatus according to Embodiment 2.

### DESCRIPTION OF THE PREFERRED EMBODIMENTS

In the present disclosure, a surface of a stage on which semiconductor chips and a wafer are mounted will be referred to as an upper surface, and a surface opposite to the upper surface will be referred to as a lower surface. Furthermore, a direction from the lower surface toward the upper surface in the stage will be referred to as up (an upward direction), and a direction opposite to the upward direction will be referred to as down (an downward direction). Furthermore, a vertical direction is a direction vertical to the upper surface of the stage, and a lateral direction is a direction orthogonal to the vertical direction, that is, a direction parallel to the upper surface of the stage. Furthermore, a plan view is a view when viewed from the direction vertical to the upper surface of the stage, and a cross-sectional view is a view when viewed from the direction parallel to the upper surface of the stage. When protrusions are arranged on the upper surface of the stage, a direction is defined based on a virtual upper surface that is a surface formed by linking ends of the protrusions.

### Embodiment 1

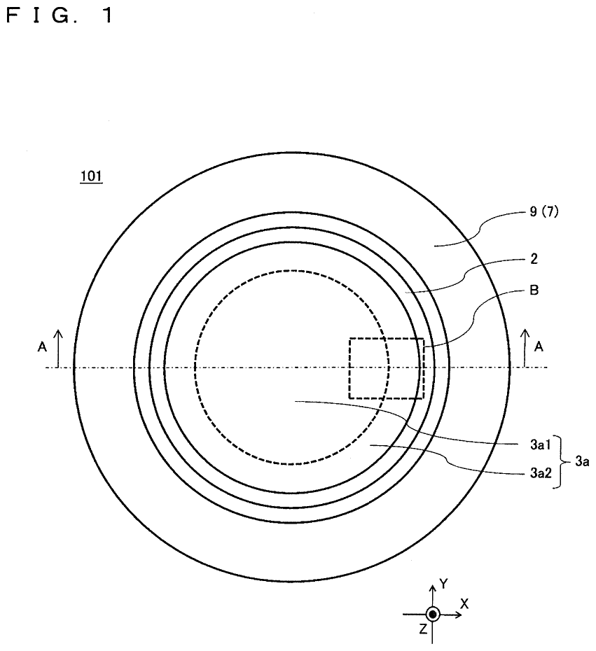

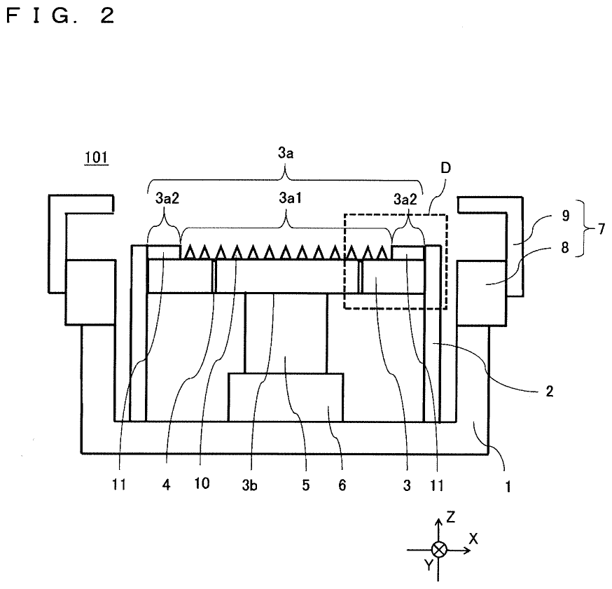

First, an outline of a semiconductor manufacturing apparatus 101 according to Embodiment 1 will be described with reference to FIGS. 1 and 2. FIG. 1 is a plan view of the semiconductor manufacturing apparatus 101, and FIG. 2 is a cross-sectional view of a cross section A-A of the semiconductor manufacturing apparatus 101 in FIG. 1. As illustrated in FIGS. 1 and 2, the semiconductor manufacturing apparatus 101 includes a housing 1, a stage frame 2 disposed inside the housing 1, a stage 3 disposed inside the stage frame 2, and a dicing sheet holder 7 disposed on the top of the perimeter of the housing 1. The housing 1, the stage frame 2, the stage 3, and the dicing sheet holder 7 are approximately circular in a plan view to match the shape of a wafer that is approximately circular. A carrier hand that is not illustrated is provided above the stage 3. The details will be hereinafter described.

The stage 3 is a mounting portion on which a wafer divided into a plurality of semiconductor chips through dicing is mounted through a dicing sheet. A stage upper surface 3a that is a surface of the stage 3 on which the dicing sheet is mounted spreads parallel to an X direction that is a first direction and a Y direction that is a second direction orthogonal to the first direction, and is shaped like an approximate circle larger than the wafer in a plan view. In other words, the stage upper surface 3a is shaped like an approximate circle with an outer peripheral edge larger in diameter than the wafer that is approximately circular. Although the present disclosure describes an example where the wafer and the stage are approximately circular, the shape is not limited to an approximate circle but may be, for example, a polygon or an oval.

Furthermore, the stage upper surface 3a includes a center portion 3a1 that is an approximately circular central region, and a perimeter portion 3a2 that is a perimeter region surrounding the center portion 3a1. As illustrated in FIG. 2, first protrusions 10 are arranged on the center portion 3a1, and a second protrusion 11 is disposed on the perimeter portion 3a2. Thus, when a wafer attached to a dicing sheet is mounted on the stage 3, the ends of the first protrusions 10 and the second protrusion 11 abut the dicing sheet, and support the wafer through the dicing sheet. Details of the first protrusions 10 and the second protrusion 11 will be described later with reference to other drawings.

The stage 3 includes a suction inlet 4 penetrating the stage upper surface 3a to a stage lower surface 3b that is opposite to the stage upper surface 3a. The suction inlet 4 is opened on the stage upper surface 3a, and is connected to one end of a suction tube (not illustrated) on the stage lower surface 3b. The other end of the suction tube is connected to a vacuum pump (not illustrated). When the vacuum pump is driven, air above the stage upper surface 3a is suctioned. Thus, when a wafer is mounted on the stage 3 through a dicing sheet and the vacuum pump is driven, gases are evacuated from the space between the stage upper surface 3a and the dicing sheet. Instead of the suction inlet 4, the vacuum pump, and the suction tube, the semiconductor manufacturing apparatus 101 may include a gas evacuation device that can evacuate gases from the space between the stage upper surface 3a and the dicing sheet.

The stage frame 2 is a frame enclosing the stage 3, for example, a cylindrical housing. A region enclosed by the stage frame 2 includes a center axis 5 having one end connected to a lower portion of the stage 3 and having the other end connected to a stage driver 6 including a motor. Driving the motor of the stage driver 6 can move the stage 3 in a Z direction that is a third direction orthogonal to the X and Y directions.

The dicing sheet holder 7 is annularly attached on the top of the perimeter of the housing 1, and is a mechanism having a function of holding a dicing sheet on which a wafer is attached when the dicing sheet is mounted on the stage 3, and pulling the dicing sheet in a direction of the outer peripheral edge, that is, a direction from the centers of the approximately circular stage 3 and the wafer toward outside. Specifically, the dicing sheet holder 7 includes a frame supporter 8, a frame pressure part 9, and a cylinder (not illustrated) that moves the frame pressure part 9 up and down. The frame attached on the perimeter portion of the dicing sheet can be sandwiched and held by the frame supporter 8 and the frame pressure part 9.

Since the surface of the frame supporter 8 in the Z direction which abuts the dicing sheet is lower than the ends of the first protrusions 10 and the second protrusion 11 arranged on the stage upper surface 3a, the frame when holding the dicing sheet is kept lower than the ends of the first protrusions 10 and the second protrusion 11. Consequently, the dicing sheet holder 7 extends the dicing sheet in a direction from the center of the stage 3 toward the outer peripheral edge.

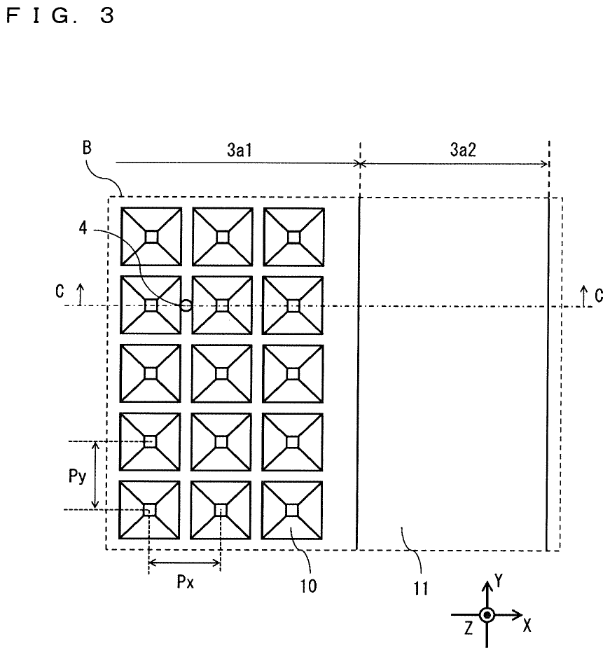

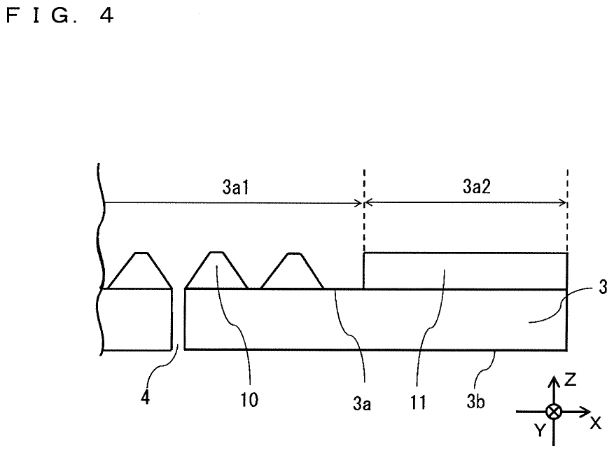

Next, the first protrusions 10 arranged on the center portion 3a1, and the second protrusion 11 disposed on the perimeter portion 3a2 in the stage upper surface 3a will be described in detail. FIG. 3 is a plan view illustrating a B portion in FIG. 1, that is, an enlarged view of a part of a boundary between the center portion 3a1 and the perimeter portion 3a2 in the stage 3 when viewed from the top. FIG. 4 is a cross-sectional view of a cross section C-C in FIG. 3, and is an enlarged view of a D portion in FIG. 2. Although the boundary between the center portion 3a1 and the perimeter portion 3a2 and the outer peripheral edge of the perimeter portion 3a2 are segments of circles, FIG. 3 simply illustrates the boundary and the outer peripheral edge by straight lines. FIGS. 3 and 4 omit the stage frame 2.

As illustrated in FIGS. 3 and 4, the plurality of first protrusions 10 are arranged so that the respective ends protrude on the center portion 3a1 of the stage upper surface 3a. Furthermore, the second protrusion 11 is disposed so that a ring-shaped and continuous end protrudes on the perimeter portion 3a2 of the stage upper surface 3a. In other words, the ends of the first protrusions 10 and the second protrusion 11 are arranged on the center portion 3a1 and the perimeter portion 3a2, respectively. Furthermore, the ends of the first protrusions 10 and the second protrusion 11 have the same height. In the present disclosure, the ends of the first protrusions 10 and the second protrusion 11 mean ends of protrusions protruding from the stage upper surface 3a. The ends of the first protrusions 10 and the second protrusion 11 should have heights that can provide the flatness allowing to hold a wafer through a dicing sheet. Thus, the first protrusions 10 and the second protrusion 11 need not always have the same height.

The first protrusions 10 arranged on the center portion 3a1 will be described further in detail. As illustrated in FIGS. 3 and 4, the plurality of first protrusions 10 are arranged in a lattice pattern so that two of the ends have a pitch Px that is a pitch in the X direction and two of the other ends have a pitch Py that is a pitch in the Y direction in a plan view. The pitch Px is equal to the pitch Py in Embodiment 1. Thus, the first protrusions 10 are arranged in a square lattice pattern. The arrangement positions of the first protrusions 10 in a plan view are not limited to those in FIG. 3. The positions should be timely determined in consideration of, for example, the size of each of semiconductor chips formed by dicing a wafer, deformation properties and adhesion of a dicing sheet, and the sucking ability of the gas evacuation device.

For example, a chip size of a semiconductor chip to be used as a power semiconductor device is a cube of approximately 5 mm to 15 mm. A pitch of ends of adjacent two of the first protrusions 10 that match the semiconductor chips of this size should be 2 mm or less, and, preferably, 0.5 mm to 1.5 mm. When the pitch of the ends of adjacent two of the first protrusions 10 is too large, the number of points that support one semiconductor chip becomes less. When the pitch is too small, intervals of points that support one semiconductor chip become shorter. In any of these cases, a stripping failure that is a failure in which semiconductor chips cannot be stripped from a dicing sheet easily occurs. The arrangement of the first protrusions 10 is not limited to rectangular lattice patterns including the square lattice pattern. The first protrusions 10 should be arranged at the aforementioned pitches.

The first protrusion 10 is shaped like a quad pyramid, and has a tapered portion that is tapered toward the end in a cross-sectional view. Since the ends of the first protrusions 10 are portions that abut a dicing sheet, preferably, the area of the portions that abut the dicing sheet is extremely small and each of the portions has a shape that abuts at a point to strip semiconductor chips from the dicing sheet. However, when the ends are pointed, the ends may scratch or damage the dicing sheet or the semiconductor chips when the ends abut the dicing sheet or the semiconductor chips. Thus, the end of the first protrusion 10 may be, for example, chamfered to obtain a plane parallel to the stage upper surface 3a to the least extent possible as illustrated in FIGS. 3 and 4. The end may be chamfered to obtain, for example, a hemispherical shape.

Although the first protrusion 10 is shaped like a quad pyramid as illustrated in FIGS. 3 and 4, the shape is not limited to this but may be a circular cone or a pyramid such as a triangular pyramid. The first protrusion 10 may have a tapered portion at an end with a shape of a pyramid or a circular cone, and a root portion with a shape of a prism or a circular cylinder closer to the root than to the tapered portion.

Next, the second protrusion 11 disposed on the perimeter portion 3a2 of the stage upper surface 3a will be described in detail. As illustrated in FIGS. 3 and 4, the second protrusion 11 is disposed on the perimeter portion 3a2 of the stage upper surface 3a so that the end protrudes from the stage upper surface 3a. The second protrusion 11 is ring-shaped to surround the center portion 3a1 in a plan view of FIG. 3, and is not tapered in the Z direction but has a rectangular cross-sectional shape in a cross-sectional view of FIG. 4. In other words, the end of the second protrusion 11 has a shape of a plane parallel to the stage upper surface 3a.

The size of each of the center portion 3a1 on which the first protrusions 10 are arranged and the perimeter portion 3a2 on which the second protrusion 11 is disposed on the stage upper surface 3a may be timely changed, depending on the size of a wafer to be manufactured and the size and the position of a semiconductor chip formed in the wafer. Specifically, the perimeter portion 3a2 should be set to correspond to positions of unnecessary chips that are small pieces of a wafer which are produced in a perimeter region of a wafer through dicing and are not to be products. A region inner than the perimeter portion 3a2 should be set to the center portion 3a1. Thus, the second protrusion 11 and the first protrusions 10 should be arranged on the perimeter portion 3a2 and the center portion 3a1, respectively. The unnecessary chips will be described later when describing effects of the present disclosure.

Currently, sizes of wafers to be used in manufacturing semiconductor devices have been standardized. Examples of diameters of outer peripheral edges of the wafers which are approximately circular and exclude orientation flats include 100 mm, 150 mm, 200 mm, 300 mm, and 450 mm. In steps of manufacturing the semiconductor devices, unnecessary chips that are not to be products are easily produced in, for example, regions between 3 and 5 mm inward from the outer peripheral edges of the wafers. At the same time, the regions hardly satisfy product specifications due to problems of, for example, variations in manufacturing processes. Sometimes, semiconductor chips to be products are not disposed in such regions as ineffective regions.

In consideration of these, the center portion 3a1 is shaped into, for example, an approximate circle whose diameter is any one of 92±2 mm, 142±2 mm, 192±2 mm, 292±2 mm, and 442±2 mm relative to a wafer of each of the standardized sizes. Then, the first protrusions 10 should be arranged so that the end of the outermost first protrusion 10 is located in a region 2 mm or less from the outer peripheral edge of the center portion 3a1 in a direction from the outer peripheral edge toward the center. In other words, assuming a distance between the center of the center portion 3a1 and one of the ends of the first protrusions 10 that are the most far from the center of the center portion 3a1 to be a first distance, the first distance should be any one of 45±2 mm, 70±2 mm, 95±2 mm, 145±2 mm, and 220±2 mm.

Furthermore, the second protrusion 11 should be disposed so that the edge of the second protrusion 11 that is the most far from the center of the center portion 3a1 in a plan view is more external than the outer peripheral edge of the wafer of each of the standardized sizes. In other words, assuming a distance between the center of the center portion 3a1 and the edge of the second protrusion 11 that is the most far from the center of the center portion 3a1 to be a second distance, the second distance should be any one of 50 mm or longer when the first distance is 45±2 mm, 75 mm or longer when the first distance is 70±2 mm, 100 mm or longer when the first distance is 95±2 mm, 150 mm or longer when the first distance is 145±2 mm, and 225 mm or longer when the first distance is 220±2 mm. These arrangements allow semiconductor chips to be disposed to overlap the center portion 3a1, and allow unnecessary chips to be disposed to overlap the perimeter portion 3a2.

The first protrusions 10 and the second protrusion 11 may be formed by attaching, to the stage 3, components to be protrusions separately produced, or may be directly formed on the stage 3 by processing the upper surface of the stage 3. When the first protrusions 10 and the second protrusion 11 are components separable from the stage 3 and are attached to the stage 3 in a method, for example, using screws, the first protrusions 10 and the second protrusion 11 can be individually detached from the stage 3, and shapes, arrangement intervals, and the number of protrusions, etc., can be changed according to circumstances.

Although the stage 3 includes the suction inlet 4 as illustrated in FIGS. 3 and 4, a plurality of the suction inlets 4 may be dispersed in a wide range in a plane of the stage upper surface 3a. The dispersed suction inlets 4 can evacuate gases more evenly from the space between the stage upper surface 3a and the dicing sheet. Furthermore, the suction inlet 4 may be circular, rectangular, or slit-shaped in a plan view.

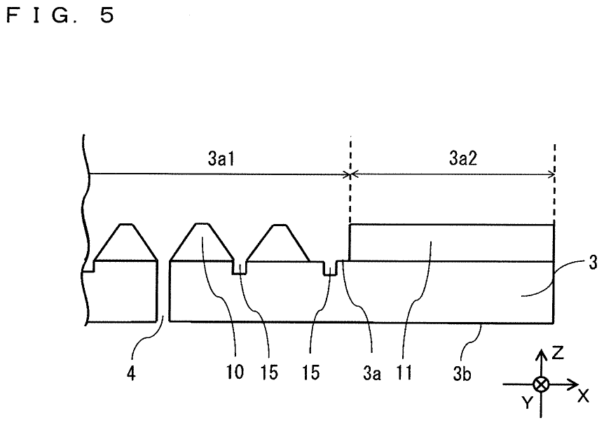

Furthermore, vacuum grooves 15 to be discharge paths in evacuating gases may be formed between the first protrusions 10 and between each of the first protrusions 10 and the second protrusion 11 on the stage upper surface 3a to effectively evacuate gases. FIG. 5 is a cross-sectional view illustrating a cross section of the stage 3 in FIG. 4 to which the vacuum grooves 15 have been added. These vacuum grooves 15 may be formed to extend in one of the X direction and the Y direction, or formed in a lattice pattern. Alternatively, one of the vacuum grooves 15 may be disposed for a plurality of protrusions in a cross-sectional view. The details of functions of the vacuum grooves 15 will be described later when describing a method of manufacturing a semiconductor device using the semiconductor manufacturing apparatus 101.

Finally, a carrier hand (not illustrated) will be described. The carrier hand is a pick-up device that picks up each of semiconductor chips attached to a dicing sheet disposed on the stage 3. The carrier hand includes, for example, an arm with an end to which an adsorption pad is attached, and can pick up each semiconductor chip with the adsorption pad absorbing and holding the semiconductor chip. The carrier hand may be a part of the semiconductor manufacturing apparatus 101, incorporated into another apparatus, for example, a manufacturing apparatus in the next step, or incorporated into a single transport robot.

Before describing the effects and advantages of the semiconductor manufacturing apparatus 101 according to Embodiment 1, the method of manufacturing a semiconductor device using the semiconductor manufacturing apparatus 101 will be first described. The method of manufacturing a semiconductor device to be described herein corresponds to manufacturing steps including stripping each of semiconductor chips formed by dicing a wafer from a dicing sheet and picking up the semiconductor chip.

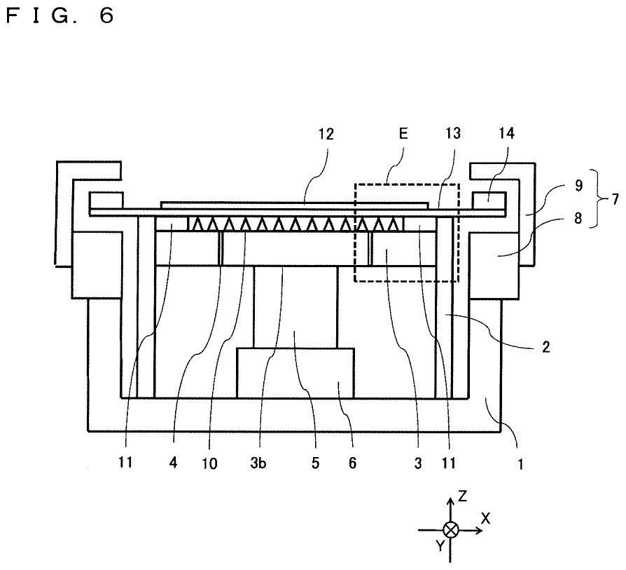

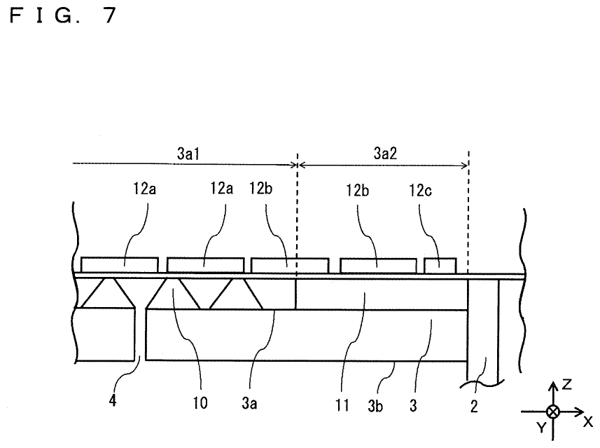

FIG. 6 is a cross-sectional view schematically illustrating the manufacturing steps after a transporting step. Furthermore, FIG. 7 is an enlarged cross-sectional view of an E portion in FIG. 6. First, the transporting step of transporting the wafer 12 and the dicing sheet 13 into the semiconductor manufacturing apparatus 101 is performed. Although FIG. 6 simply illustrates the wafer 12, the wafer 12 attached to the upper surface of the dicing sheet 13 in a dicing step prior to the transporting step is actually diced. In other words, the wafer 12 is divided into semiconductor chips 12a to be products, unnecessary chips 12b that are identical in size to the semiconductor chips 12a but are not to be products, and unnecessary chips 12c that are smaller in size than the semiconductor chips 12a and are not to be products as illustrated in FIG. 7. Although the unnecessary chips 12b are identical in size to the semiconductor chips 12a, the unnecessary chips 12b imposed in the vicinity of the outer peripheral edge of the wafer 12 are not to be products due to risks in quality management. These chips which remain attached to the dicing sheet 13 are transported to the semiconductor manufacturing apparatus 101 in the transporting step to be supported by and disposed on the first protrusions 10 and the second protrusion 11 on the stage 3 through the dicing sheet 13.

The dicing sheet 13 is an adhesive sheet with adhesion on one surface, for example, a resin sheet obtained by adding an acrylic pressure sensitive adhesive to a base material containing polyolefin. The dicing sheet 13 has adhesion high enough to fasten the wafer 12 so as not to move when being diced and further fasten the semiconductor chips 12a, the unnecessary chips 12b, and the unnecessary chips 12c divided by the dicing so as not to be stripped and scattered.

A frame 14 is attached to an upper surface of a region outside a region to which the wafer 12 is attached to the dicing sheet 13. The frame 14 is used when the dicing sheet 13 is transported and held in the semiconductor manufacturing apparatus 101.

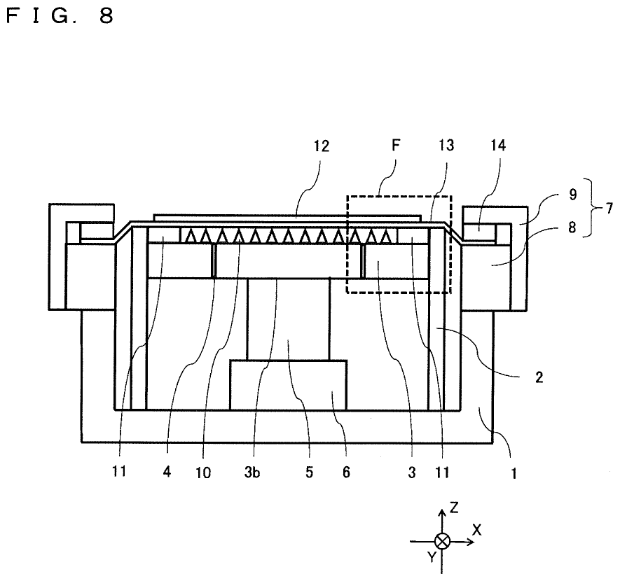

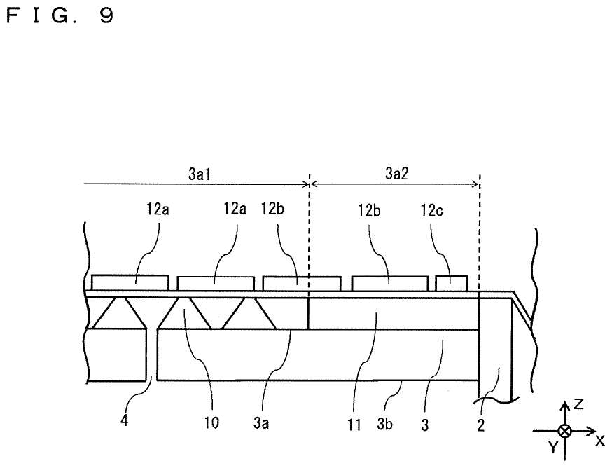

FIG. 8 is a cross-sectional view schematically illustrating the manufacturing steps after a dicing sheet holding step. Furthermore, FIG. 9 is an enlarged cross-sectional view of an F portion in FIG. 8. After the transporting step, the dicing sheet holding step of holding the dicing sheet 13 and pulling the dicing sheet 13 outside is performed. After the dicing sheet 13 is transported into the semiconductor manufacturing apparatus 101 in the transporting step, the frame pressure part 9 of the dicing sheet holder 7 attached to a perimeter portion of the housing 1 goes down to sandwich the frame 14 between the frame supporter 8 and the frame pressure part 9 for holding the dicing sheet 13.

Although the dicing sheet 13 is held without any move while being disposed on the stage upper surface 3a in the dicing sheet holding step, the dicing sheet 13 is pulled from the centers of the approximately circular stage 3 and the wafer toward the outer peripheral edge because the frame 14 is held at a position lower than that of the stage upper surface 3a. This enlarges the elastic dicing sheet 13 toward a direction of the outer peripheral edge and widens intervals between the semiconductor chips 12a, the unnecessary chips 12b, and the unnecessary chips 12c that are adjacent to each other, which prevents a malfunction of interference between the chips when being picked up.

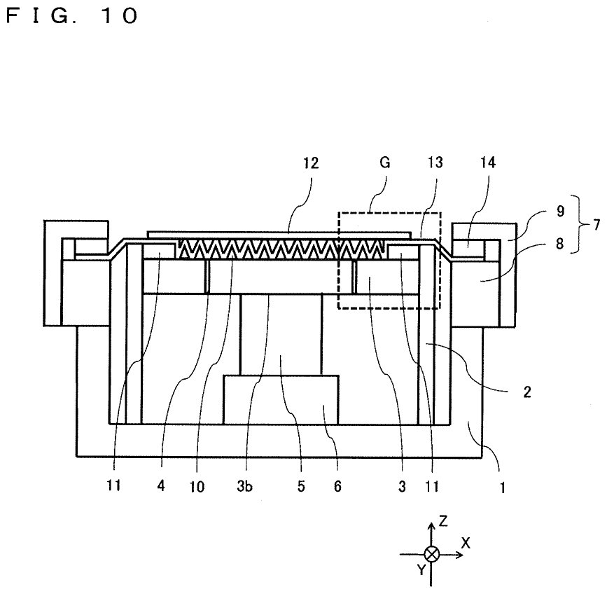

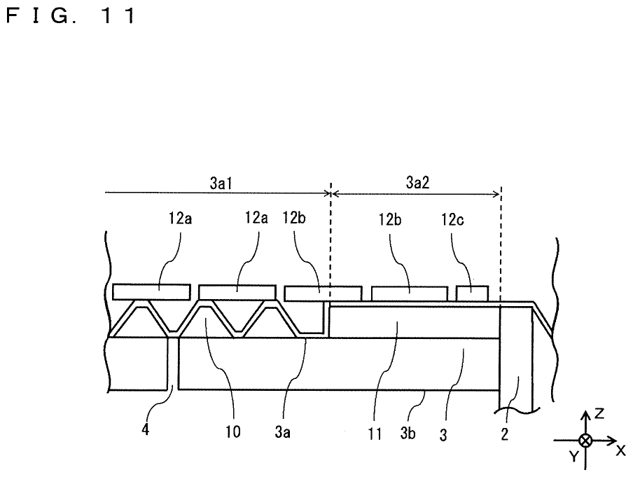

FIG. 10 is a cross-sectional view schematically illustrating the manufacturing steps after a stripping step. Furthermore, FIG. 11 is an enlarged cross-sectional view of a G portion in FIG. 10. After the dicing sheet holding step, the stripping step of stripping the semiconductor chips 12a from the dicing sheet 13 is performed. When the vacuum pump operates with the dicing sheet 13 being held, the vacuum pump evacuates gases from the space between the dicing sheet 13 and the stage upper surface 3a. As illustrated in FIG. 11, portions of the dicing sheet 13 other than the portions abutted by the ends of the first protrusions 10 and the second protrusion 11 are suctioned and become deformed in a direction approaching the stage upper surface 3a.

Here, the first protrusions 10 are disposed on the center portion 3a1 of the stage upper surface 3a. In the center portion 3a1, the semiconductor chips 12a to be products are mainly disposed. When the vacuum pump evacuates gases, the portions of the dicing sheet 13 other than the portions abutted by the ends of the first protrusions 10 become deformed in the direction approaching the stage upper surface 3a, and are stripped from the back side of the semiconductor chips 12a.

When the pitches of arranging the first protrusions 10 are large with respect to the size of each of the semiconductor chips 12a, the number of the first protrusions 10 abutting the semiconductor chips 12a becomes less. In such a case, deformation of the dicing sheet 13 causes the semiconductor chips 12a to fall between the adjacent first protrusions 10 and tilt, which sometimes causes a failure in stripping the dicing sheet 13. Conversely, when the pitch of arranging the first protrusions 10 is small with respect to the size of each of the semiconductor chips 12a, a region between the adjacent first protrusions 10 is narrowed. This inhibits the deformation of the dicing sheet 13, and sometimes causes a failure in stripping the dicing sheet 13. Since small pieces such as the unnecessary chips 12c are not disposed in the center portion 3a1, intervals of arranging the first protrusions 10 can be optimized according to the size of the semiconductor chip 12a.

In contrast, the second protrusion 11 is disposed on the perimeter portion 3a2 of the stage upper surface 3a. In the perimeter portion 3a2, the unnecessary chips 12b and the unnecessary chips 12c that are not to be products are mainly disposed. In the perimeter portion 3a2, the dicing sheet 13 abuts the face of the end of the second protrusion 11 and is not deformed. Thus, the unnecessary chips 12b and the unnecessary chips 12c are hardly stripped from the dicing sheet 13. Particularly, since the ring-shaped and continuous second protrusion 11 is disposed and abuts the wafer 12 at the flat face in Embodiment 1, the unnecessary chips 12c attached to the dicing sheet 13 can be held without being stripped even when the size of each of the unnecessary chips 12c is small.

In FIG. 11, the dicing sheet 13 follows the shape of the first protrusions 10 and is completely adsorbed on the first protrusions 10 in the center portion 3a1. However, the dicing sheet 13 need not always be completely adsorbed in such a manner. Instead, the portions of the dicing sheet 13 other than the portions abutted by the ends of the first protrusions 10 should be deformed in the direction approaching the stage upper surface 3a until the portions of the dicing sheet 13 are stripped from the lower surfaces of the semiconductor chips 12a.

The dicing sheet 13 completely adsorbed on the stage upper surface 3a sometimes closes the suction inlet 4, and causes a region in which gases are not sufficiently evacuated to remain in a part of the plane of the stage upper surface 3a. In such a case, the vacuum grooves 15 in FIG. 5 can ensure discharge paths through which air is discharged in evacuating gases, even when the dicing sheet 13 is completely adsorbed on the first protrusions 10 in the center portion 3a1. These vacuum grooves 15 formed in a wide region of the stage upper surface 3a enable gases to be evacuated more evenly in a plane, from the space between the stage upper surface 3a and the dicing sheet 13.

After the stripping step, a pick-up step of picking up each of the semiconductor chips 12a from the dicing sheet 13 and transporting the semiconductor chip 12a outside of the semiconductor manufacturing apparatus 101 is performed. The pick-up step is, for example, a step of adsorbing the upper surface of each of the semiconductor chips 12a using the carrier hand with the adsorption pad, lifting the semiconductor chip 12a upward, stripping the semiconductor chip 12a from the dicing sheet 13, and housing the semiconductor chip 12a in a carrier rack to be transported to the next step. In the stripping step before the pick-up step, portions of the dicing sheet 13 other than the portions abutted by the ends of the first protrusions 10 are stripped from the semiconductor chips 12a. Thus, the semiconductor chips 12a are held and attached on the dicing sheet 13 only at the portions abutted by the ends of the first protrusions 10. Thus, the carrier hand can easily pick up each of the semiconductor chips 12a with a small force.

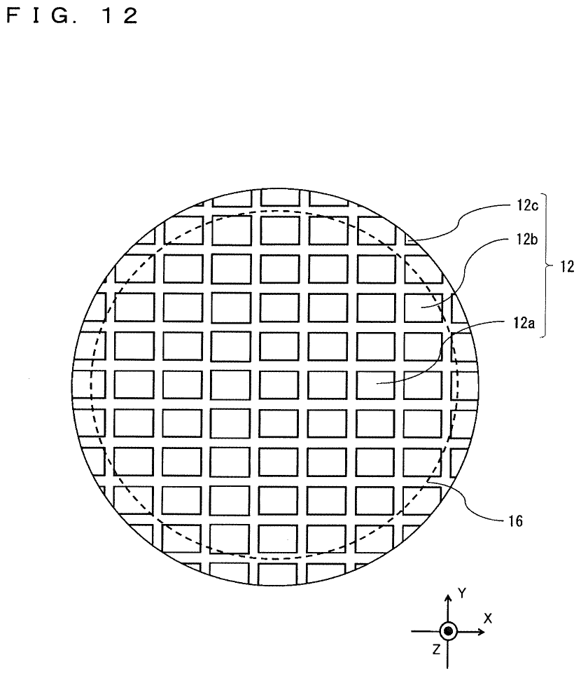

The effects of the semiconductor manufacturing apparatus 101 according to Embodiment 1 will be described. Before describing the effects, the structure of the wafer 12 will be described in detail. FIG. 12 is a plan view of the wafer 12 attached to the dicing sheet 13 and diced, when viewed from the top. As illustrated in FIG. 12, the wafer 12 attached to the upper surface of the dicing sheet 13 in the dicing step prior to the transporting step is diced along dicing lines extending in the X direction and the Y direction orthogonal to the X direction to be divided into the rectangular semiconductor chips 12a to be products, the unnecessary chips 12b that are also rectangular and identical in size to the semiconductor chips 12a but are not to be products, and the unnecessary chips 12c that are not rectangular, are smaller in size than the semiconductor chips 12a, and are not to be products. Regions between the semiconductor chips 12a, the unnecessary chips 12b, and the unnecessary chips 12c are the dicing lines. After the wafer 12 is diced, the regions are air gaps from which the wafer 12 has been removed.

In manufacturing a semiconductor device, an approximately circular boundary 16 is set in the wafer 12. A center region inside the boundary 16 is set to an effective region in which products can be disposed. Furthermore, a perimeter region outside the boundary 16 is set to an ineffective region in which chips to be products cannot be disposed due to risks in quality management caused by, for example, variations in manufacturing processes. As illustrated in FIG. 12, although the unnecessary chips 12b are identical in size to the semiconductor chips 12a, the unnecessary chips 12b are not to be products because all or a part of the chips are in the ineffective region outside the boundary 16. Furthermore, the unnecessary chips 12c are not to be products because the unnecessary chips 12c are not only at the outermost circumference of the wafer 12 and in the ineffective region outside the boundary 16 but also smaller in size than the semiconductor chips 12a. The width of the perimeter region of the wafer 12 differs depending on, for example, the specification of a product. The width is set, for example, approximately between 3 to 5 mm. In other words, the boundary 16 is shaped into an approximate circle whose diameter approximately ranges from 6 to 10 mm, which is smaller than the approximately circular wafer 12.

In the semiconductor manufacturing apparatus 101, the first protrusions 10 with tapered portions are arranged on the center portion 3a1 of the stage upper surface 3a, and the second protrusion 11 without any tapered portion is disposed on the perimeter portion 3a2 of the stage upper surface 3a. The first protrusions 10 abut the semiconductor chips 12a at respective points in the center portion 3a1. This result produces effects in that the semiconductor chips 12a are held by the first protrusions 10 without being tilted due to deformation of the dicing sheet 13 and the semiconductor chips 12a are easily stripped from the dicing sheet 13 in regions between the points at which the first protrusions 10 abut the semiconductor chips 12a.

In contrast, the second protrusion 11 without any tapered portion on the perimeter portion 3a2 abuts, at a plane, the unnecessary chips 12b and the unnecessary chips 12c in the perimeter region of the wafer 12. This produces an effect of preventing deformation of the dicing sheet 13 and unintended stripping of the unnecessary chips 12b and the unnecessary chips 12c from the dicing sheet 13 when evacuating gases. Particularly, since the second protrusion 11 abuts, at a plane, the unnecessary chips 12c smaller in size than the semiconductor chips 12a, the unintended stripping of the unnecessary chips 12c is prevented.

Next, the advantages of the semiconductor manufacturing apparatus 101 according to Embodiment 1 will be described. The unnecessary chips 12b and the unnecessary chips 12c produced by dicing are never used as products, and are separately transferred to a disposal step of disposing the unnecessary chips 12b and the unnecessary chips 12c while being attached to the dicing sheet 13. Since the unnecessary chips 12c are smaller in size than the semiconductor chips 12a, the unnecessary chips 12c tend to be stripped from the dicing sheet 13 without any intention. Particularly, when gases are evacuated with the unnecessary chips 12c abutting tapered protrusions at respective points as in the conventional technologies, deformation of the dicing sheet 13 sometimes causes the unnecessary chips 12c to be stripped from the dicing sheet 13. When the unnecessary chips 12c are stripped, a chip flying malfunction occurs, that is, the unnecessary chips 12c fly off onto the semiconductor chips 12a to be products which are around the unnecessary chips 12c, and damage the semiconductor chips 12a.

The semiconductor manufacturing apparatus 101 according to Embodiment 1 includes the first protrusions 10 with the tapered portions on the center portion 3a1 of the stage upper surface 3a to correspond to the center region inside the boundary 16 of the wafer 12. The first protrusions 10 produce advantages of facilitating stripping, from the dicing sheet 13, the semiconductor chips 12a disposed in the center region of the wafer 12, and preventing the stripping failure. The semiconductor manufacturing apparatus 101 further includes the second protrusion 11 without any tapered portion on the perimeter portion 3a2 of the stage upper surface 3a to correspond to the perimeter region outside the boundary 16. The second protrusion 11 produces advantages of reducing the unintended stripping of the unnecessary chips 12c in the perimeter region of the wafer 12 and preventing the chip flying malfunction.

### Embodiment 2

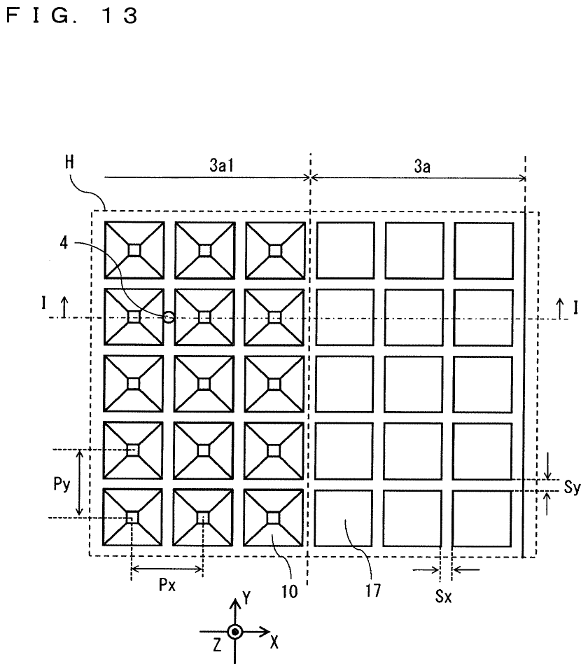

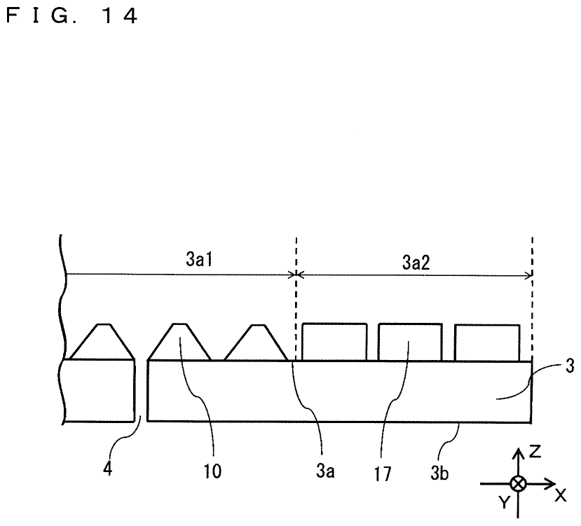

An outline of a semiconductor manufacturing apparatus according to Embodiment 2 will be described with reference to FIGS. 13 and 14. FIG. 13 is a plan view illustrating an H portion that is a part of a boundary between the center portion 3a1 and the perimeter portion 3a2 of the stage 3 when viewed from the top. The H portion corresponds to the B portion in FIG. 1 according to Embodiment 1, and FIG. 13 corresponds to FIG. 3 according to Embodiment 1. FIG. 14 is a cross-sectional view of a cross section I-I in FIG. 13, and corresponds to FIG. 4 according to Embodiment 1. Although the boundary between the center portion 3a1 and the perimeter portion 3a2 and the outer peripheral edge of the perimeter portion 3a2 are segments of circles, FIG. 13 simply illustrates the boundary and the outer peripheral edge by straight lines.

The semiconductor manufacturing apparatus according to Embodiment 2 evacuates gases from the space between the stage upper surface 3a and the dicing sheet 13 to strip the semiconductor chips 12a from the dicing sheet 13, similarly to Embodiment 1. The semiconductor manufacturing apparatus according to Embodiment 1 includes the first protrusions 10 with the tapered portions on the center portion 3a1 of the stage upper surface 3a and the second protrusion 11 that is ring-shaped and continuous in a plan view without any tapered portion on the perimeter portion 3a2 of the stage upper surface 3a. In contrast, the semiconductor manufacturing apparatus according to Embodiment 2 includes the first protrusions 10 with the tapered portions on the center portion 3a1 of the stage upper surface 3a similarly to Embodiment 1, and a plurality of second protrusions 17 without any tapered portion on the perimeter portion 3a2 of the stage upper surface 3a. The details will be hereinafter described. The overlapping description on the same structures as those according to Embodiment 1 may be omitted.

As illustrated in FIGS. 13 and 14, the first protrusions 10 are disposed on the center portion 3a1 of the stage upper surface 3a so that respective ends protrude from the stage upper surface 3a, similarly to Embodiment 1. The arrangement of the first protrusions 10 is identical to that according to Embodiment 1. A pitch of the adjacent first protrusions 10 should be 2 mm or less, and, preferably, 0.5 mm to 1.5 mm.

In addition, the plurality of second protrusions 17 each of which is shaped like a square pole are disposed on the perimeter portion 3a2 of the stage upper surface 3a so that respective ends protrude from the stage upper surface 3a, The lengths of clearances between the adjacent second protrusion 17, that is, gaps Sx and Sy are each 1 mm or less, which are dimensions less than the pitch Px and the pitch Py of the first protrusions 10 on the center portion 3a1. The shape of each of the second protrusions 17 is not limited to a square pole but may be a circular cylinder or a prism such as a triangle pole.

The ends of the first protrusions 10 and the second protrusions 17 have, for example, the same height. In the present disclosure, the ends of the first protrusions 10 and the second protrusions 17 mean ends of protrusions protruding from the stage upper surface 3a. The ends of the first protrusions 10 and the second protrusions 17 should have heights that can provide the flatness allowing to hold the wafer 12 through the dicing sheet 13. Thus, the first protrusions 10 and the second protrusions 17 need not always have the same height.

The arrangement positions of the first protrusions 10 and the second protrusions 17 according to Embodiment 2 are identical to those of the first protrusions 10 and the second protrusion 11 according to Embodiment 1. In other words, the first protrusions 10 should be arranged so that the first distance that is a distance between the center of the center portion 3a1 and the end of the first protrusion 10 that is the most far from the center of the center portion 3a1 in a plan view is any one of 45±2 mm, 70±2 mm, 95±2 mm, 145±2 mm, and 220±2 mm to correspond to the wafer of each of the standardized sizes. Furthermore, the second protrusions 17 should be arranged so that the second distance that is a distance between the center of the center portion 3a1 and the edge of the second protrusion 17 that is the most far from the center of the center portion 3a1 in a plan view is any one of 50 mm or longer when the first distance is any one of 45±2 mm, 75 mm or longer when the first distance is 70±2 mm, 100 mm or longer when the first distance is 95±2 mm, 150 mm or longer when the first distance is 145±2 mm, and 225 mm or longer when the first distance is 220±2 mm.

The advantages of the semiconductor manufacturing apparatus according to Embodiment 2 will be described. The center portion 3a1 according to Embodiment 2 is identical in structure to that according to Embodiment 1, and has an effect of easily stripping the semiconductor chips 12a from the dicing sheet 13 (i.e., the stripping failure hardly occurs) in regions abutted by the first protrusions 10 to the center portion 3al. On the perimeter portion 3a2, the second protrusions 17 without any tapered portion abut, at a plane, the unnecessary chips 12b and the unnecessary chips 12c in the perimeter region of the wafer 12. Thus, evacuating gases prevents deformation of the dicing sheet 13 that is in contact with the unnecessary chips 12b and the unnecessary chips 12c. This produces an effect of preventing unintended stripping of the unnecessary chips 12b and the unnecessary chips 12c from the dicing sheet 13.

The second protrusions 17 are not continuous on the perimeter portion 3a2 according to Embodiment 2. The adjacent second protrusions 17 have a clearance therebetween. This clearance functions as a discharge path in evacuating gases and prevents creation of air pockets on the faces of the ends of the second protrusions 17. Adherence of the faces of the ends of the second protrusions 17 to the dicing sheet 13 without any clearance can prevent unintended stripping of the second protrusions 17 from the dicing sheet 13. Larger clearances between the second protrusions 17 may deform the dicing sheet 13 because the dicing sheet 13 enters the clearances in evacuating gases. This may strip the unnecessary chips 12b and the unnecessary chips 12c from the dicing sheet 13 without any intention. Here, making the lengths of the clearances between the adjacent second protrusions 17, that is, the gaps Sx and Sy each 1 mm or less produces advantages of reducing deformation of the dicing sheet 13, preventing stripping of the unnecessary chips 12b and the unnecessary chips 12c, and preventing the chip flying malfunction.

Some embodiments of the present disclosure described above are presented as examples. The embodiments can be variously omitted, modified, or changed without departing from the spirit and scope of the disclosure. The embodiments can be combined. Scope of the present disclosure is thus indicated by the appended claims rather than by the foregoing description, and all changes that come within the meaning and range of equivalency of the claims are intended to be embraced therein.

A summary of various aspects of the present disclosure will be hereinafter described as Appendixes.
[Appendix 1] A semiconductor manufacturing apparatus that strips semiconductor chips from a dicing sheet on one surface of which an approximately circular wafer including the semiconductor chips is attached, the semiconductor chips being obtained by dividing the wafer into small pieces through dicing, the semiconductor manufacturing apparatus comprising:
a stage on which the wafer is disposed through the dicing sheet, the stage including a plurality of protrusions supporting the wafer;
a dicing sheet holder holding the dicing sheet; and
a gas evacuation device evacuating gases from a space between the stage and the dicing sheet,
wherein the plurality of protrusions include a plurality of first protrusions each including a tapered portion that is tapered in a cross-sectional view and an end disposed on a center portion that is an approximately circular region in a center of the stage in a plan view, and at least one second protrusion without any tapered portion which includes an end disposed on a perimeter portion surrounding the center portion in the plan view.
[Appendix 2] The semiconductor manufacturing apparatus according to appendix 1, wherein the at least one second protrusion comprises a second protrusion that is ring-shaped and continuous around the center portion in the plan view.
[Appendix 3] The semiconductor manufacturing apparatus according to appendix 1, wherein the at least one second protrusion comprises a plurality of second protrusions that are not continuous in the plan view.
[Appendix 4] The semiconductor manufacturing apparatus according to appendix 3, wherein a length of a gap between adjacent two of the second protrusions is 1 mm or less.
[Appendix 5] The semiconductor manufacturing apparatus according to any one of appendixes 1 to 4,
   wherein a pitch between the ends of adjacent two of the first protrusions is 2 mm or less.
[Appendix 6] The semiconductor manufacturing apparatus according to any one of appendixes 1 to 5,
   wherein the semiconductor chips are disposed in a center region of the wafer, unnecessary chips that are not the semiconductor chips and are small pieces are disposed in a perimeter region surrounding the center region, and the end of at least one of the first protrusions overlaps the semiconductor chips and the end of the at least one second protrusion overlaps the unnecessary chips in the plan view when the wafer is disposed on the stage.
[Appendix 7] The semiconductor manufacturing apparatus according to any one of appendixes 1 to 6,
   wherein a first distance that is a distance between the center of the center portion and the end of one of the first protrusions that is most far from the center of the center portion in the plan view is any one of 45±2 mm, 70±2 mm, 95±2 mm, 145±2 mm, and 220±2 mm.
[Appendix 8] The semiconductor manufacturing apparatus according to appendix 7,
   wherein a second distance that is a distance between the center of the center portion and an edge of the at least one second protrusion which is most far from the center of the center portion in the plan view is any one of 50 mm or longer when the first distance is 45±2 mm, 75 mm or longer when the first distance is 70±2 mm, 100 mm or longer when the first distance is 95±2 mm, 150 mm or longer when the first distance is 145±2 mm, and 225 mm or longer when the first distance is 220±2 mm.
[Appendix 9] The semiconductor manufacturing apparatus according to any one of appendixes 1 to 8,
   wherein the dicing sheet holder has a function of extending the dicing sheet in a direction from the center of the stage toward an outer peripheral edge of the stage.
[Appendix 10] The semiconductor manufacturing apparatus according to any one of appendixes 1 to 9, comprising
   a pick-up device picking up each of the semiconductor chips from the stage.

While the invention has been shown and described in detail, the foregoing description is in all aspects illustrative and not restrictive. It is therefore understood that numerous modifications and variations can be devised without departing from the scope of the invention.

What is claimed is:

1. A semiconductor manufacturing apparatus that strips semiconductor chips from a dicing sheet on one surface of which an approximately circular wafer including the semiconductor chips is attached, the semiconductor chips being obtained by dividing the wafer into small pieces through dicing, the semiconductor manufacturing apparatus comprising:
a stage on which the wafer is disposed through the dicing sheet, the stage including a plurality of protrusions supporting the wafer;
a dicing sheet holder holding the dicing sheet; and
a gas evacuation device evacuating gases from a space between the stage and the dicing sheet,
wherein the plurality of protrusions include a plurality of first protrusions each including a tapered portion that is tapered in a cross-sectional view and an end disposed on a center portion that is an approximately circular region in a center of the stage in a plan view, and at least one second protrusion without any tapered portion which includes an end disposed on a perimeter portion surrounding the center portion in the plan view.

2. The semiconductor manufacturing apparatus according to claim 1,
wherein the at least one second protrusion comprises a second protrusion that is ring-shaped and continuous around the center portion in the plan view.

3. The semiconductor manufacturing apparatus according to claim 1,
wherein the at least one second protrusion comprises a plurality of second protrusions that are not continuous in the plan view.

4. The semiconductor manufacturing apparatus according to claim 3,
wherein a length of a gap between adjacent two of the second protrusions is 1 mm or less.

5. The semiconductor manufacturing apparatus according to claim 1,
wherein a pitch between the ends of adjacent two of the first protrusions is 2 mm or less.

6. The semiconductor manufacturing apparatus according to claim 1,
wherein the semiconductor chips are disposed in a center region of the wafer, unnecessary chips that are not the semiconductor chips and are small pieces are disposed in a perimeter region surrounding the center region, and the end of at least one of the first protrusions overlaps the semiconductor chips and the end of the at least one second protrusion overlaps the unnecessary chips in the plan view when the wafer is disposed on the stage.

7. The semiconductor manufacturing apparatus according to claim 1,
wherein a first distance that is a distance between the center of the center portion and the end of one of the first protrusions that is most far from the center of the center portion in the plan view is any one of 45±2 mm, 70±2 mm, 95±2 mm, 145±2 mm, and 220±2 mm.

8. The semiconductor manufacturing apparatus according to claim 7,
wherein a second distance that is a distance between the center of the center portion and an edge of the at least one second protrusion which is most far from the center of the center portion in the plan view is any one of 50 mm or longer when the first distance is 45±2 mm, 75 mm or longer when the first distance is 70±2 mm, 100 mm or longer when the first distance is 95±2 mm, 150 mm or longer when the first distance is 145±2 mm, and 225 mm or longer when the first distance is 220±2 mm.

9. The semiconductor manufacturing apparatus according to claim 1,
wherein the dicing sheet holder has a function of extending the dicing sheet in a direction from the center of the stage toward an outer peripheral edge of the stage.

10. The semiconductor manufacturing apparatus according to claim 1, comprising
a pick-up device picking up each of the semiconductor chips from the stage.
